(19) United States
(12) Patent Application Publication
(10) Pub. No.: US 2025/0006754 A1
(43) Pub. Date: Jan. 2, 2025

(54) IMAGING DEVICE AND SEMICONDUCTOR DEVICE

(71) Applicant: SONY SEMICONDUCTOR SOLUTIONS CORPORATION, KANAGAWA (JP)

(72) Inventor: KEN TOMITA, KANAGAWA (JP)

(21) Appl. No.: 18/709,582

(22) PCT Filed: Nov. 8, 2022
(86) PCT No.: PCT/JP2022/041598

§ 371 Date: May 13, 2024

(30) Foreign Application Priority Data
Nov. 19, 2021 (JP) 2021-188603

(51) Int. Cl. H01L 27/146

(52) U.S. Cl. CPC H01L 27/14614; H01L 27/14603; H01L 27/14643

(57) ABSTRACT

An imaging device and a semiconductor device that can reduce the capacitance of a gate electrode are provided. The imaging device includes a photoelectric conversion element and a semiconductor device that reads charge generated by the photoelectric conversion element. The semiconductor device includes a semiconductor substrate and a field-effect transistor provided on the first surface side of the semiconductor substrate. The field-effect transistor includes a gate electrode including a buried gate portion buried from the first surface of the semiconductor substrate toward an inside of the semiconductor substrate, a gate insulating film disposed between the semiconductor substrate and the gate electrode, a source region provided on the semiconductor substrate and connected to one side of the gate electrode in a gate length direction of the gate electrode, and a drain region connected to the other side of the gate electrode in the gate length direction. The buried gate portion includes a first site, and a second site located between at least one of the source region and the drain region and the first region, and having a thickness from the first surface smaller than that of the first region.

### TECHNICAL FIELD

The present disclosure relates to an imaging device and a semiconductor device.

### BACKGROUND ART

A transistor disclosed in PTL 1 is known as a transistor used in a pixel region of a complementary metal oxide semiconductor (CMOS) image sensor. The gate electrode of this transistor has a plane portion and a fin portion. The fin portion is formed to be buried from the plane portion toward the inside of the semiconductor substrate.

### CITATION LIST

### Patent Literature

[PTL 1]

JP 2017-183636 A

### SUMMARY

### Technical Problem

When the transistor disclosed in PTL 1 is used as an amplification transistor of a CMOS image sensor, as the capacitance generated between the fin portion of the gate electrode and the drain region increases, noise included in an amplified pixel signal increases. Thus, the characteristics of the CMOS image sensor may deteriorate. It is desirable to reduce the capacitance of a gate electrode having a fin portion.

The present disclosure has been made in view of the above-described circumstances, and an object of the present disclosure is to provide an imaging device and a semiconductor device that can reduce the capacitance of a gate electrode.

### Solution to Problem

An imaging device according to one aspect of the present disclosure includes a photoelectric conversion element and a semiconductor device that reads charge generated by the photoelectric conversion element. The semiconductor device includes a semiconductor substrate and a field-effect transistor provided on a first surface side of the semiconductor substrate. The field-effect transistor includes a gate electrode including a buried gate portion buried from the first surface of the semiconductor substrate toward an inside of the semiconductor substrate; a gate insulating film disposed between the semiconductor substrate and the gate electrode; a source region provided on the semiconductor substrate and connected to one side of the gate electrode in a gate length direction of the gate electrode; and a drain region connected to the other side of the gate electrode in the gate length direction. The buried gate portion includes a first site; and a second site located between at least one of the source region and the drain region and the first site, and having a thickness from the first surface smaller than that of the first site.

According to this, the overlapping area between one of the source region and the drain region and the buried gate portion in the gate length direction can be reduced, and the capacitance generated between one of the source region and the drain region and the gate electrode can be reduced. An imaging device that can reduce the capacitance of a gate electrode can be provided.

A semiconductor device according to one aspect of the present disclosure includes a semiconductor substrate and a field-effect transistor provided on a first surface side of the semiconductor substrate. The field-effect transistor includes a gate electrode including a buried gate portion buried from the first surface of the semiconductor substrate toward an inside of the semiconductor substrate; a gate insulating film disposed between the semiconductor substrate and the gate electrode; a source region provided on the semiconductor substrate and connected to one side of the gate electrode in a gate length direction of the gate electrode; and a drain region connected to the other side of the gate electrode in the gate length direction. The buried gate portion includes a first site; and a second site located between at least one of the source region and the drain region and the first site, and having a thickness from the first surface smaller than that of the first site.

According to this, the overlapping area between one of the source region and the drain region and the buried gate portion in the gate length direction can be reduced, and the capacitance generated between one of the source region and the drain region and the gate electrode can be reduced. A semiconductor device that can reduce the capacitance of a gate electrode can be provided.

### BRIEF DESCRIPTION OF DRAWINGS

FIG. 1 is a schematic diagram showing an exemplary configuration of an imaging device applied to each embodiment of the present disclosure.

FIG. 2A is a plan view showing an exemplary configuration of a MOS transistor according to a first embodiment of the present disclosure.

FIG. 2B is a cross-sectional view showing an exemplary configuration of the MOS transistor according to the first embodiment of the present disclosure.

FIG. 2C is a cross-sectional view showing an exemplary configuration of the MOS transistor according to the first embodiment of the present disclosure.

FIG. 3A is a cross-sectional view showing a method for manufacturing the MOS transistor according to the first embodiment of the present disclosure in the order of steps.

FIG. 3B is a cross-sectional view showing a method for manufacturing the MOS transistor according to the first embodiment of the present disclosure in the order of steps.

FIG. 3C is a cross-sectional view showing a method for manufacturing the MOS transistor according to the first embodiment of the present disclosure in the order of steps.

FIG. 4A is a plan view showing a MOS transistor according to a first modified example of the first embodiment of the present disclosure.

FIG. 4B is a cross-sectional view showing a MOS transistor according to the first modified example of the first embodiment of the present disclosure.

FIG. 5 is a cross-sectional view showing a MOS transistor according to a second modified example of the first embodiment of the present disclosure.

FIG. 6 is a cross-sectional view showing a MOS transistor according to a third modified example of the first embodiment of the present disclosure.

FIG. 7 is a cross-sectional view showing a MOS transistor according to a fourth modified example of the first embodiment of the present disclosure.

FIG. 8 is a cross-sectional view showing an exemplary configuration of a MOS transistor according to a second embodiment of the present disclosure.

FIG. 9 is a cross-sectional view showing an exemplary configuration of a MOS transistor according to a third embodiment of the present disclosure.

FIG. 10 is a cross-sectional view showing an exemplary configuration of a MOS transistor according to a fourth embodiment of the present disclosure.

FIG. 11 is a plan view showing a transfer transistor according to a first modified example of the fourth embodiment of the present disclosure.

FIG. 12 is a plan view showing a transfer transistor according to a second modified example of the fourth embodiment of the present disclosure.

### DESCRIPTION OF EMBODIMENTS

Embodiments of the present disclosure will be described below with reference to the drawings. Description will be given in the following order.
1. Exemplary schematic configuration of imaging device
2. First embodiment
2-1. Exemplary configuration
2-2. Manufacturing method
2-3. Effects of first embodiment
2-4. First modified example
2-5. Second modified example
2-6. Third modified example
2-7. Fourth modified example
3. Second embodiment
3-1. Exemplary configuration
3-2. Effects of second embodiment
4. Third embodiment
4-1. Exemplary configuration
4-2. Effects of third embodiment
5. Fourth embodiment
5-1. Exemplary configuration
5-2. Effects of fourth embodiment
5-3. First modified example
5-4. Second modified example
6. Other embodiments

In descriptions of the drawings referred to in the following description, same or similar portions will be denoted by same or similar reference signs. However, it should be noted that the drawings are schematic, and the relationships between thicknesses and planar dimensions, ratios of thicknesses of respective layers, and the like are different from actual ones. Therefore, specific thicknesses and dimensions should be determined by considering the following descriptions. In addition, it is of course that the drawings include portions where mutual dimensional relationships and ratios differ between the drawings.

It is to be understood that definitions of directions such as upward, downward, and the like in the following description are merely definitions provided for the convenience of explanation and are not intended as limiting technical ideas of the present disclosure. For example, it is obvious that when an object is observed after being rotated by 90 degrees, up-down is converted into and interpreted as left-right, and when an object is observed after being rotated by 180 degrees, up-down is interpreted as being inverted.

In the following descriptions, the terms “X-axis direction”, “Y-axis direction”, and “Z-axis direction” may be used to describe directions. For example, the X-axis direction and the Y-axis direction are directions parallel to the front surface 4a of a semiconductor substrate 4. The Y-axis direction is also the gate length direction of a gate electrode 6. The X-axis direction and the Y-axis direction are also referred to as “horizontal directions”. The Z-axis direction is a direction which vertically intersects the front surface 4a of the semiconductor substrate 4. The Z-axis direction is also a direction parallel to the depth direction from the front surface 4a of the semiconductor substrate 4 or the thickness direction from the front surface 4a. The X-axis direction, the Y-axis direction, and the Z-axis direction are directions orthogonal to each other.

### 1. Schematic Exemplary Configuration of Imaging Device

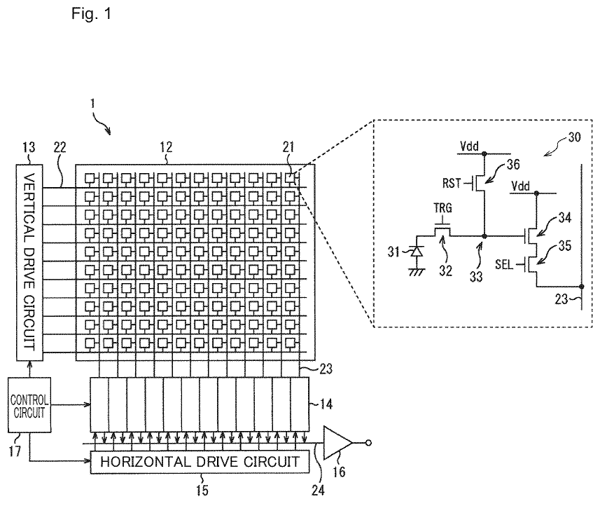

FIG. 1 is a schematic diagram showing an exemplary configuration of an imaging device 1 applied to each embodiment of the present disclosure. As shown in FIG. 1, the imaging device 1 includes a pixel region 12, a vertical drive circuit 13, a column signal processing circuit 14, a horizontal drive circuit 15, an output circuit 16, and a control circuit 17.

The pixel region 12 is a light-receiving region that receives light collected by an optical system (not shown). In the pixel region 12, a plurality of sensor pixels 21 are arranged in a matrix. The plurality of sensor pixels 21 are connected to the vertical drive circuit 13 on a row-by-row basis via horizontal signal lines 22, and to the column signal processing circuit 14 on a column-by-column basis via vertical signal lines 23. The plurality of sensor pixels 21 each output a pixel signal of a level corresponding to the amount of light received. An image of the subject is constructed from these pixel signals.

The vertical drive circuit 13 sequentially supplies a drive signal for driving (transferring, selecting, resetting, and the like) each sensor pixel 21 for each row of the plurality of sensor pixels 21 to the sensor pixel 21 via the horizontal signal line 22. The column signal processing circuit 14 performs correlated double sampling (CDS) processing on the pixel signal output from the plurality of sensor pixels 21 via the vertical signal line 23 to perform AD conversion on the pixel signal and remove reset noise.

The horizontal drive circuit 15 sequentially supplies the column signal processing circuit 14 with a drive signal for causing the column signal processing circuit 14 to output a pixel signal to the data output signal line 24 for each column of the plurality of sensor pixels 21. The output circuit 16 amplifies the pixel signal supplied from the column signal processing circuit 14 via the data output signal line 24 at a timing according to the drive signal of the horizontal drive circuit 15, and outputs it to the subsequent signal processing circuit. The control circuit 17 controls the driving of each block inside the imaging device 1. For example, the control circuit 17 generates a clock signal according to the drive cycle of each block and supplies it to each block.

The sensor pixel 21 includes a photodiode 31 (an example of a “photoelectric conversion element” in the present disclosure), a transfer transistor 32, a floating diffusion 33, an amplification transistor 34, a selection transistor 35, and a reset transistor 36. The transfer transistor 32, floating diffusion 33, amplification transistor 34, selection transistor 35, and reset transistor 36 constitute a readout circuit 30 that reads out the charge (pixel signal) generated by photoelectric conversion in the photodiode 31.

The photodiode 31 is a photoelectric conversion unit that photoelectrically converts incident light into charges and accumulates them, and has an anode terminal grounded and a cathode terminal connected to the transfer transistor 32. The transfer transistor 32 is electrically connected to the photodiode 31. The transfer transistor 32 is driven according to a transfer signal TRG supplied from the vertical drive circuit 13, and when the transfer transistor 32 is turned on, the charges accumulated in the photodiode 31 are transferred to the floating diffusion 33. The floating diffusion 33 is a floating diffusion region connected to the gate electrode of the amplification transistor 34 and having a predetermined storage capacity, and temporarily stores the charge transferred from the photodiode 31.

The amplification transistor 34 outputs a pixel signal of a level corresponding to the charge accumulated in the floating diffusion 33 (that is, the potential of the floating diffusion 33) to the vertical signal line 23 via the selection transistor 35. In other words, due to the configuration in which the floating diffusion 33 is connected to the gate electrode of the amplification transistor 34, the floating diffusion 33 and the amplification transistor 34 function as a converter that amplifies the charge generated in the photodiode 31 and convert it into a pixel signal of a level corresponding to the charge.

The selection transistor 35 is driven according to a selection signal SEL supplied from the vertical drive circuit 13, and when the selection transistor 35 is turned on, the pixel signal output from the amplification transistor 34 can be output to the vertical signal line 23. The reset transistor 36 is driven according to the reset signal RST supplied from the vertical drive circuit 13, and when the reset transistor 36 is turned on, the charges accumulated in the floating diffusion 33 are discharged to the drain power supply potential Vdd, and the floating diffusion 33 is reset.

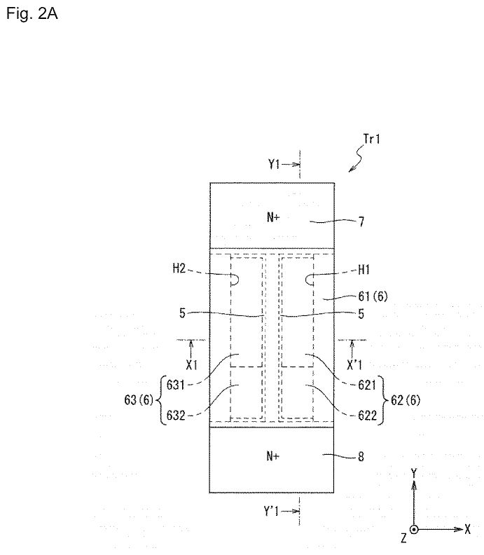

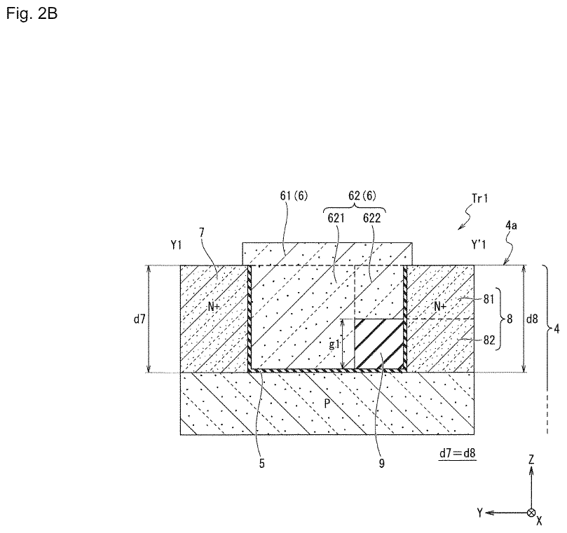

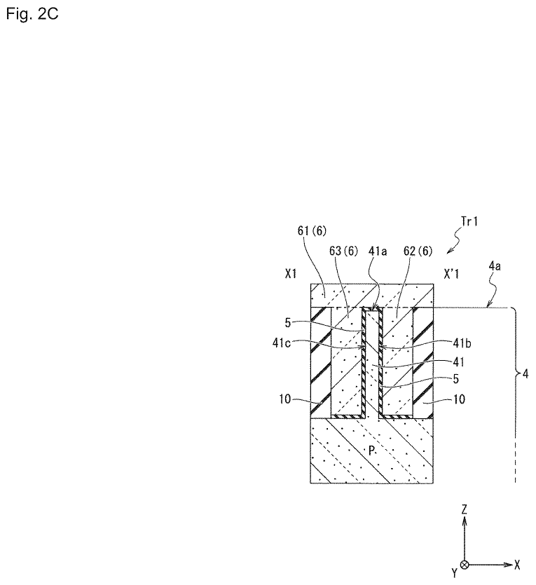

The amplification transistor 34 shown in FIG. 1 is configured of, for example, any one of metal oxide semiconductor (MOS) transistors Tr1 to Tr1D (an example of the “field-effect transistor” of the present disclosure; see FIGS. 2A to 2C) described below.

### 2. First Embodiment

### 2-1. Exemplary Configuration

Next, a semiconductor device included in the sensor pixel 21 shown in FIG. 1 will be described. FIG. 2A is a plan view showing an exemplary configuration of the MOS transistor Tr1 according to the first embodiment of the present disclosure. FIGS. 2B and 2C are cross-sectional views showing an exemplary configuration of the MOS transistor Tr1 according to the first embodiment of the present disclosure. Specifically, FIG. 2B shows a cross-section of the plan view shown in FIG. 2A taken along line Y1-Y′1 parallel to the Y axis. FIG. 2C shows a cross-section of the plan view shown in FIG. 2A, taken along line X1-X′1 parallel to the X-axis.

As shown in FIGS. 2A to 2C, the semiconductor device according to the first embodiment includes a semiconductor substrate 4, a metal oxide semiconductor (MOS) transistor Tr1 provided in the semiconductor substrate 4, and an element separation layer 10 provided in the semiconductor substrate 4. The semiconductor substrate 4 is made of, for example, single crystal silicon. The MOS transistor Tr1 is provided on the front surface 4a (an example of the “first surface” of the present disclosure) of the semiconductor substrate 4. The element separation layer 10 is an insulating film for electrically separating elements adjacent in the horizontal direction parallel to the front surface 4a, and is made of, for example, a silicon oxide film (SiO₂ film).

The MOS transistor Tr1 is a first conductivity-type (for example, N-type) transistor. The MOS transistor Tr1 includes a second conductivity-type (for example, P-type) semiconductor region 41 in which a channel is formed, a gate insulating film 5, a gate electrode 6, an N-type source region 7 provided on the semiconductor substrate 4, and a drain region 8 provided on the semiconductor substrate 4.

The semiconductor region 41 is, for example, a portion of the semiconductor substrate 4 and is made of single crystal silicon. The semiconductor region 41 is a region formed by etching a portion of the front surface 4a side of the semiconductor substrate 4, and has a fin shape, for example.

A first trench H1 is provided on one side of the semiconductor region 41, and a second trench H2 is provided on the other side of the semiconductor region 41. In the X-axis direction, the first trench H1 and the second trench H2 are arranged side by side. A first buried gate portion 62 of the gate electrode 6 is arranged in the first trench H1. A second buried gate portion 63 of the gate electrode 6 is arranged in the second trench H2. The first buried gate portion 62 and the second buried gate portion 63 will be described later. The semiconductor region 41 is sandwiched in the Y-axis direction by the first buried gate portion 62 arranged in the first trench H1 and the second buried gate portion 63 arranged in the second trench H2.

The gate insulating film 5 is provided so as to cover an upper surface 41a, a first side surface 41b, and a second side surface 41c of the semiconductor region 41. The upper surface 41a of the semiconductor region 41 is a portion of the front surface 4a of the semiconductor substrate 4. The first side surface 41b is located at one side of the upper surface 41a in the Y-axis direction. The second side surface 41c is located at the other side of the upper surface 41a in the Y-axis direction. The gate insulating film 5 is made of, for example, SiO₂ film.

The gate electrode 6 covers the semiconductor region 41 over the gate insulating film 5. For example, the gate electrode 6 includes a top gate portion 61 facing the upper surface 41a of the semiconductor region 41 with the gate insulating film 5 interposed therebetween, a first buried gate portion 62 facing the first side surface 41b of the semiconductor region 41 with the gate insulating film 5 interposed therebetween, and a second buried gate portion 63 facing the second side surface 41c of the semiconductor region 41 with the gate insulating film 5 interposed therebetween. The first buried gate portion 62 and the second buried gate portion 63 are connected to the lower surface of the top gate portion 61.

In this way, the gate electrode 6 can simultaneously apply a gate voltage to the upper surface 41a, the first side surface 41b, and the second side surface 41c of the semiconductor region 41. That is, the gate electrode 6 can simultaneously apply gate voltage to the semiconductor region 41 from a total of three directions: the upper side and both left and right sides. In this way, the gate electrode 6 can completely deplete the semiconductor region 41. The gate electrode 6 is made of, for example, a polysilicon (Poly-Si) film.

Note that since the top gate portion 61 is provided horizontally with respect to the front surface 4a of the semiconductor substrate 4 and has a planar shape, it may also be referred to as a horizontal gate electrode or a plane portion. Since the first buried gate portion 62 and the second buried gate portion 63 are provided vertically with respect to the front surface 4a of the semiconductor substrate 4 and have a fin shape, they may also be referred to as vertical gate electrodes or fin portions.

In addition, the MOS transistor Tr1 and the MOS transistors Tr1A to Tr1D, Tr2, Tr3, and Tr4 to Tr4B, which will be described later, have a shape in which the first buried gate portion 62 and the second buried gate portion 63 of the gate electrode 6 are disposed in the first trench H1 and the second trench H2. Thus, these MOS transistors may also be referred to as MOS transistors with a trench gate structure. Alternatively, since the semiconductor regions 41 of the MOS transistors Tr1 to Tr1D, Tr2, Tr3, and Tr4 to Tr4B have a fin shape, these MOS transistors may also be referred to as Fin Field-effect transistors (FinFETs). Alternatively, the MOS transistors Tr1 to Tr1D, Tr2, Tr3, and Tr4 to Tr4B may also be referred to as trench FinFETs because of the above-described two shapes.

The source region 7 and the drain region 8 are each a first conductivity-type (for example, N-type) impurity diffusion layer. The source region 7 and the drain region 8 are provided on and near the front surface 4a of the semiconductor substrate 4, respectively. In the X-axis direction, the source region 7 is connected to one side of the semiconductor region 41, and the drain region 8 is connected to the other side of the semiconductor region 41.

The source region 7 and the drain region 8 are formed with the same impurity concentration and at the same depth. For example, the N-type impurity contained in the source region 7 and drain region 8 is phosphorus or arsenic. The source region 7 and the drain region 8 are formed by ion-implanting the same type of N-type impurity into the semiconductor substrate 4 at the same dose and with the same implantation energy, and by diffusing and activating it with the same thermal profile. In this way, the source region 7 and the drain region 8 are formed so that the same type of N-type impurity has the same concentration in the depth direction from the front surface 4a of the semiconductor substrate 4. As shown in FIG. 2B, if the depth from the surface of the source region 7 is d7, and the depth from the surface of the drain region 8 is d8, the depths d7 and d8 have the same value or almost the same value (d7=d8).

Further, in the MOS transistor Tr1, an insulating film 9 is provided at the bottom of each of the first trench H1 and the second trench H2, and at a position adjacent to the drain region 8. The insulating film 9 is, for example, a SiO₂ film. The thickness of the insulating film 9 is, for example, thicker than the thickness of the gate insulating film 5, and is in the range of several nm to several hundred nm.

Due to the presence of the insulating film 9, the first buried gate portion 62 has a first site 621 and a second site 622 whose depth from the front surface 4a of the semiconductor substrate 4 is smaller than the first site 621. Specifically, the first buried gate portion 62 includes the first site 621 disposed at the bottom of the first trench H1 without the insulating film 9 interposed therebetween, and the second site 622 disposed at the bottom of the first trench H1 with the insulating film 9 interposed therebetween. The depth from the front surface 4a of the first trench H1 to the insulating film 9 is shallower in the region where the second site 622 is arranged than in the region where the first site 621 is arranged. A step g1 due to the insulating film 9 is present at the bottom of the first trench H1. The thickness of the second site 622 from the front surface 4a is smaller than the thickness of the first site 621 from the front surface 4a by the amount of the insulating film 9 (that is, the amount of the step g1).

In the MOS transistor Tr1, the first site 621 of the first buried gate portion 62 is located on the source region 7 side, and the second site 622 is located on the drain region 8 side. The second site 622 is located between the first site 621 and the drain region 8.

Similarly, due to the presence of the insulating film 9, the second buried gate portion 63 has a first site 631 and a second site 632 thinner than the first site 631. Specifically, the second buried gate portion 63 includes the first site 631 disposed at the bottom of the second trench H2 without the insulating film 9 interposed therebetween, and the second site 632 disposed at the bottom of the second trench H2 with the insulating film 9 interposed therebetween. The depth from the front surface 4a of the second trench H2 to the insulating film 9 is shallower in the region where the second site 632 is arranged than in the region where the first site 631 is arranged. A step g1 due to the insulating film 9 is present at the bottom of the second trench H2. The thickness of the second site 632 from the front surface 4a is smaller than the thickness of the first site 631 from the front surface 4a by the amount of the insulating film 9 (that is, the amount of the step g1).

In the MOS transistor Tr1, the first site 631 of the second buried gate portion 63 is located on the source region 7 side, and the second site 632 is located on the drain region 8 side. The second site 632 is located between the first site 631 and the drain region 8.

In this way, it is possible to reduce the gate-drain capacitance Cgd generated between the gate electrode 6 and the drain region 8 compared to the case where the insulating film 9 is not present on the drain region 8 side (that is, the case where the step g1 is not present).

Furthermore, the effective depth of the drain region 8 is shallower than when the insulating film 9 is not present on the drain region 8 side (that is, when the step g1 is not present). The drain region 8 has an effective region 81 that actually functions as a drain, and a low effective region 82 that has a lower function as a drain than the effective region 81. The low effective region 82 is located below the effective region 81.

### 2-2. Manufacturing Method

Next, an example of a method for manufacturing the MOS transistor Tr1 according to the first embodiment of the present disclosure will be described. The MOS transistor Tr1 is manufactured using various devices including a film forming device (including a chemical vapor deposition (CVD) device, a thermal oxidation device, a resist coating device, and the like), an exposure device, an ion implantation device, an annealing device, an etching device, a chemical mechanical polishing (CMP) device. Hereinafter, these devices are collectively referred to as a manufacturing apparatus.

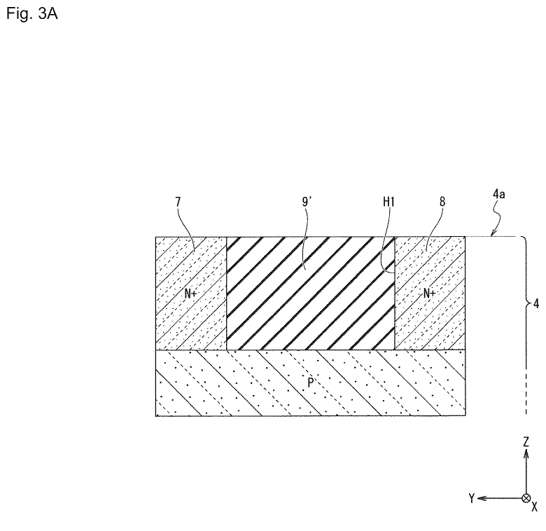

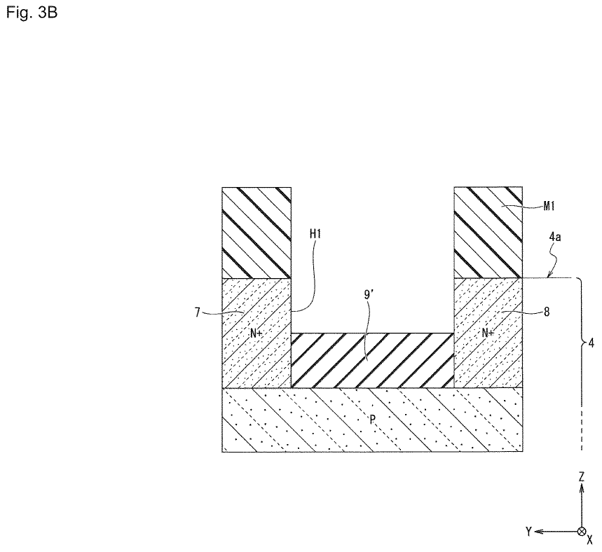

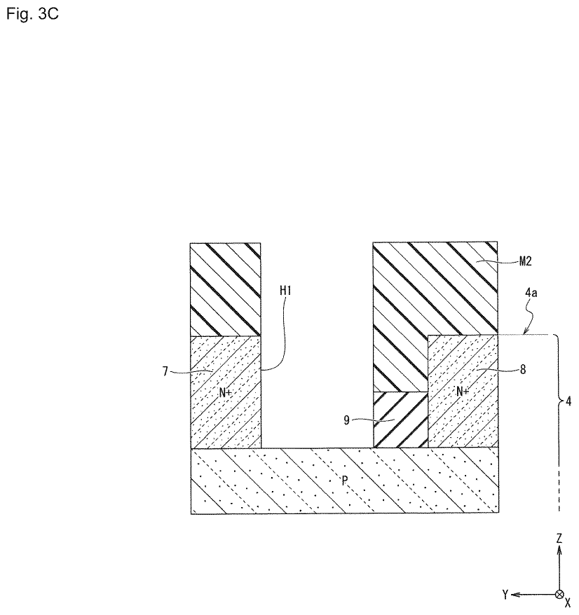

FIGS. 3A to 3C are cross-sectional views showing a method for manufacturing the MOS transistor Tr1 according to the first embodiment of the present disclosure in the order of steps. As shown in FIG. 3A, the manufacturing apparatus forms a source region 7 and a drain region 8 on the front surface 4a side of the semiconductor substrate 4. In addition, before and after this, the manufacturing apparatus forms a first trench H1 and a second trench H2 (see FIG. 2A) on the front surface 4a side of the semiconductor substrate 4. By forming the first trench H1 and the second trench H2, the semiconductor region 41 having the upper surface 41a, the first side surface 41b, and the second side surface 41c shown in FIG. 2C is defined.

Next, the manufacturing apparatus fills the first trench H1 and the second trench H2 with an insulating film 9′. The insulating film 9′ is, for example, a SiO₂ film. The insulating film 9′ is formed by, for example, a CVD method. Next, the manufacturing apparatus performs a CMP process on the surface of the insulating film 9′ to planarize it. In this way, the surface of the insulating film 9′ becomes flush with the front surface 4a of the semiconductor substrate 4.

Next, as shown in FIG. 3B, the manufacturing apparatus forms a mask M1 on the front surface 4a side of the semiconductor substrate 4. The mask M1 has a shape that opens above the first trench H1 and above the second trench H2, and covers the other regions. The mask M1 is made of photoresist, for example. Next, the manufacturing apparatus performs an etching process on the insulating film 9′ exposed from the mask M1 to adjust the thickness of the insulating film 9′ to a preset value. For example, the insulating film 9 is subjected to a wet etching process so that the thickness of the insulating film 9′ becomes the value of the step g1 shown in FIG. 2B. After that, the manufacturing apparatus removes the mask M1.

Next, as shown in FIG. 3C, the manufacturing apparatus forms a mask M2 on the front surface 4a side of the semiconductor substrate 4. The mask M2 has a shape that partially opens above the first trench H1 and above the second trench H2, and covers the other regions. The mask M2 has a shape that covers a region where the insulating film 9 (see FIG. 2B) is formed in each of the first trench H1 and the second trench H2.

Next, the manufacturing apparatus performs an etching process to remove the insulating film 9′ exposed from the mask M2. In this way, the manufacturing apparatus forms the insulating film 9 disposed on the drain region 8 side from the insulating film 9′. After forming the insulating film 9, the manufacturing apparatus removes the mask M2.

Next, the manufacturing apparatus performs thermal oxidation treatment on the semiconductor substrate 4 to form a gate insulating film 5 (see FIG. 2C). The gate insulating film 5 is formed on the upper surface 41a, the first side surface 41b, and the second side surface 41c (see FIG. 2C) of the semiconductor region 41 sandwiched between the first trench H1 and the second trench H2.

Next, the manufacturing apparatus forms an electrode material (for example, polysilicon) on the front surface 4a of the semiconductor substrate 4 on which the gate insulating film 5 is formed, and fills the first trench H1 and the second trench H2.

Next, the manufacturing apparatus patterns the electrode material to form the gate electrode 6 using photolithography and etching techniques. Through these steps, the MOS transistor Tr1 shown in FIGS. 2A to 2C is completed.

Note that in the above-described manufacturing method, it has been described that, after forming the source region 7 and the drain region 8, the first trench H1, the second trench H2, the insulating film 9, the gate insulating film 5, and the gate electrode 6 are formed in this order. However, the method for manufacturing the MOS transistor Tr1 is not limited to this. For example, the source region 7 and drain region 8 may be formed after the gate electrode 6 is formed. In this case, the source region 7 and drain region 8 may be formed in a self-aligned manner by implanting N-type impurity ions into the front surface 4a side of the semiconductor substrate 4 using the gate electrode 6 and the like as a mask. Even with such a method, the MOS transistor Tr1 can be manufactured.

### 2-3. Effects of First Embodiment

As described above, the imaging device 1 according to the first embodiment of the present disclosure includes the photodiode 31 and a semiconductor device (for example, the readout circuit 30) that reads out the charge generated by the photodiode 31. The semiconductor device includes the semiconductor substrate 4 and the MOS transistor Tr provided on the front surface 4a side of the semiconductor substrate 4. The MOS transistor Tr includes the gate electrode 6 including the first buried gate portion 62 buried from the front surface 4a of the semiconductor substrate 4 toward the inside of the semiconductor substrate 4, the gate insulating film 5 disposed between the semiconductor substrate 4 and the gate electrode 6, the source region 7 provided on the semiconductor substrate 4 and connected to one side of the gate electrode 6 in the gate length direction (for example, the Y-axis direction) of the gate electrode 6, and the drain region 8 connected to the other side of the gate electrode 6 in the gate length direction. The first buried gate portion 62 includes the first site 621 and the second site 622 located between the source region 7 and the first site 621, and having a thickness from the front surface 4a of the semiconductor substrate 4 smaller than the first site 621.

According to this, the overlapping area between the first buried gate portion 62 and the drain region 8 in the Y-axis direction can be reduced compared to the case where the step g1 due to the insulating film 9 is not present, and the gate-drain capacitance Cgd generated between the gate electrode 6 and the drain region 8 can be reduced. Since Cgd is reduced, variations in Cgd can be reduced.

Furthermore, as described above, the MOS transistor Tr1 can be suitably used as the amplification transistor 34 of the readout circuit 30 because the Cgd is reduced. By using the MOS transistor Tr1 as the amplification transistor 34 of the readout circuit 30, it is possible to reduce the electron number equivalent noise including feedback noise as shown in the following equation (1), and improve the conversion efficiency in differential mode as shown in the following equation (2).

$$[ Math . 1 ]$$

$$Electron number equivalent noise = \frac{{N}_{AMP}}{e \cdot G} \cdot {C}_{FD\_total} \qquad ( 1 )$$

In Equation (1),
N_{AMP} is the noise of the amplification transistor,
C_{FD_total} is the total capacity of the floating diffusion,
e is the elementary charge, and
G is the source follower gain.
C_{FD_total} includes Cgd, and as Cgd increases, C_{FD_total} also increases. Therefore, by reducing Cgd, it is possible to reduce electron number equivalent noise including feedback noise.

$$[ Math . 2 ]$$

$${η}_{DA} = \frac{e}{\frac{{C}_{fd\_total}}{- Av} + ( {C}_{gd} + {C}_{fd\_vsl} )} \qquad ( 2 )$$

In Equation (2),
η_{DA} is the conversion efficiency in differential mode,
e is the elementary charge,
C_{fd_total} is the total capacity of the floating diffusion,
Av is open loop gain=gm/gds, and
C_{fd-vsl} is the FD-VSL capacitance.
C_{fd_total} includes Cgd, and as Cgd increases, C_{fd_total} also increases. Therefore, by reducing Cgd, the conversion efficiency η_{DA} in the differential mode can be increased.

### 2-4. First Modified Example

In the first embodiment described above, it has been described that the gate electrode 6 has a first buried gate portion and a second buried gate portion. That is, it has been described that the gate electrode 6 has two buried gate portions. However, in the embodiment of the present disclosure, the configuration of the gate electrode 6 is not limited to this. The number of buried gate portions included in the gate electrode 6 may be one, or three or more.

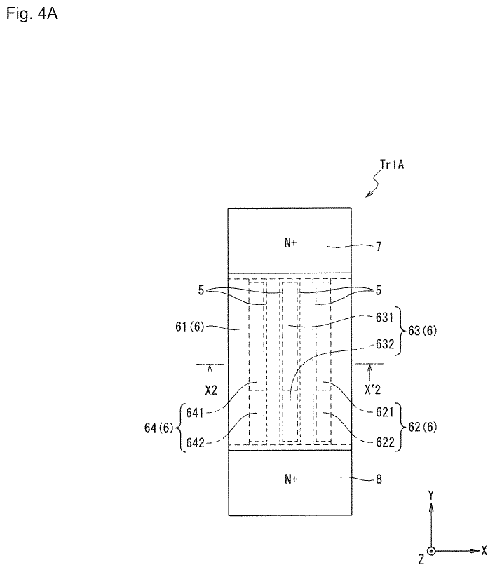

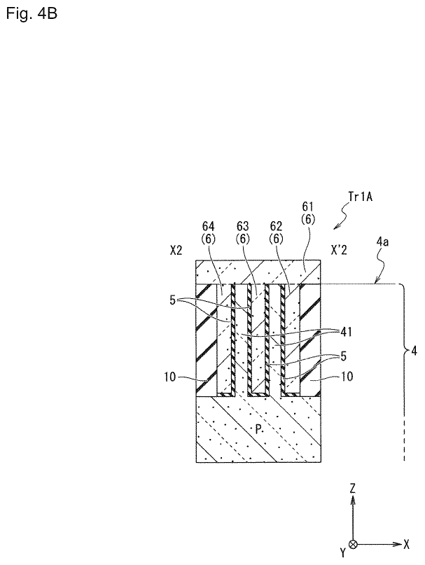

FIG. 4A is a plan view showing a MOS transistor Tr1A according to the first modified example of the first embodiment of the present disclosure. FIG. 4B is a cross-sectional view showing the MOS transistor Tr1A according to the first modified example of the first embodiment of the present disclosure. FIG. 4B shows a cross-section of the plan view shown in FIG. 4A, taken along line X2-X′2 parallel to the X-axis.

As shown in FIGS. 4A and 4B, in the MOS transistor Tr1A according to the first modified example of the first embodiment, the gate electrode 6 includes a top gate portion 61, a first buried gate portion 62, a second buried gate portion 63, and a third buried gate portion 64. The third buried gate portion 64 is connected to the lower surface of the top gate portion 61 similarly to the first buried gate portion 62 and the second buried gate portion 63. The third buried gate portion 64 is arranged to face the second buried gate portion 63 with the semiconductor region 41 and the gate insulating film 5 covering both sides thereof interposed therebetween. Further, similarly to the first buried gate portion 62 and the second buried gate portion 63, the third buried gate portion 64 also has a first site 641 and a second site 642 thinner than the first site 641 due to the presence of the insulating film 9.

The MOS transistor Tr1A has first sites 621, 631, and 641 and second sites 622, 632, and 642 which are thinner than the first sites 621, 631, and 641. The second site 622, 632, and 642 face the drain region 8. In this way, the MOS transistor Tr1A can reduce the gate-drain capacitance Cgd similarly to the above-described MOS transistor Tr1.

### 2-5. Second Modified Example

In the first embodiment described above, it has been described that the step g1 due to the insulating film 9 is provided at the bottom of each of the first trench H1 and the second trench H2. In the embodiment of the present disclosure, this step g1 may be a multi-step. Furthermore, the surface or side surface of the insulating film 9 causing the step g1 may not be horizontal or perpendicular to the front surface 4a of the semiconductor substrate 4, but may be inclined.

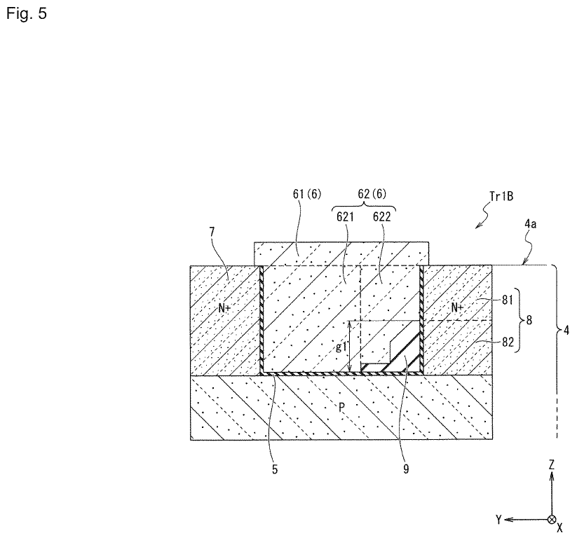

FIG. 5 is a cross-sectional view showing a MOS transistor Tr1B according to the second modified example of the first embodiment of the present disclosure. As shown in FIG. 5, in the MOS transistor Tr1B according to the second modified example of the first embodiment, the step g1 due to the insulating film 9 is a multi-stage. Further, a portion of the surface of the insulating film 9 is inclined with respect to the front surface 4a of the semiconductor substrate 4. As a result, the depth of the first trench H1 from the front surface 4a becomes shallower stepwise or gradually from the region where the first site 621 of the first buried gate portion 62 is arranged to the region where the second site 622 is arranged. The thickness of the first buried gate portion 62 from the front surface 4a decreases stepwise or gradually from the first site 621 to the second site 622. Although not shown in FIG. 5, the insulating film 9 under the second buried gate portion 63 also has a structure in which a portion of the surface is inclined, similarly to the insulating film 9 under the first buried gate portion 62.

Even with such a configuration, since the MOS transistor Tr1B has the thin second sites 622 and 632, which face the drain region 8, the gate-drain capacitance Cgd can be reduced similarly to the MOS transistor Tr1.

### 2-6. Third Modified Example

In the first embodiment described above, it has been described that the insulating film 9 is not disposed under the first site 621 of the first buried gate portion 62 and under the first site 631 of the second buried gate portion 63. However, the present disclosure is not limited thereto. In the embodiment of the present disclosure, a portion of the insulating film 9 may also be arranged under the first sites 621 and 631.

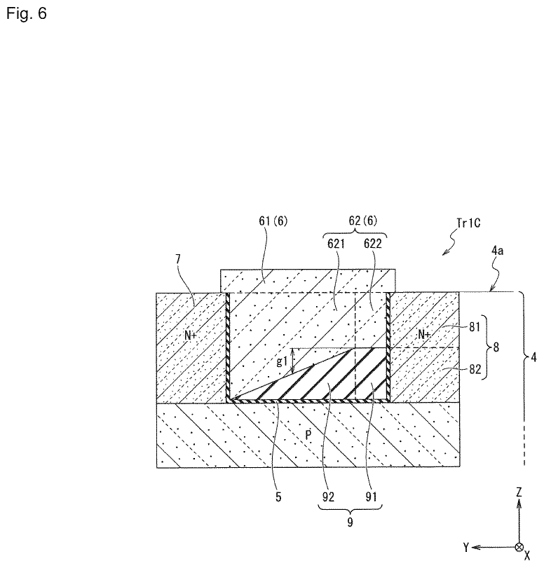

FIG. 6 is a cross-sectional view showing a MOS transistor Tr1C according to the third modified example of the first embodiment of the present disclosure. As shown in FIG. 6, in the MOS transistor Tr1C according to the third modified example of the first embodiment, the insulating film 9 includes a thin film portion 91 and a thick film portion 92 that is thicker than the thin film portion 91. The thin film portion 91 is located below the first site 621, and the thick film portion 92 is located below the second site 622. Further, the surface of the thin film portion 91 is inclined with respect to the front surface 4a of the semiconductor substrate 4 so that the thickness of the thin film portion 91 becomes thinner as it approaches the source region 7 (that is, the step g1 becomes larger as it approaches the source region 7). Although not shown in FIG. 6, the insulating film 9 under the second buried gate portion 63 also has the same configuration as the insulating film 9 under the first buried gate portion 62.

Even with such a configuration, the MOS transistor Tr 1C has the thin second sites 622 and 632, which face the drain region 8, so that the gate-drain capacitance Cgd can be reduced similarly to the MOS transistor Tr1.

### 2-7. Fourth Modified Example

In the first embodiment described above, it has been described that the depth d7 of the source region 7 and the depth d8 of the drain region 8 are the same or almost the same. However, the embodiments of the present disclosure are not limited thereto.

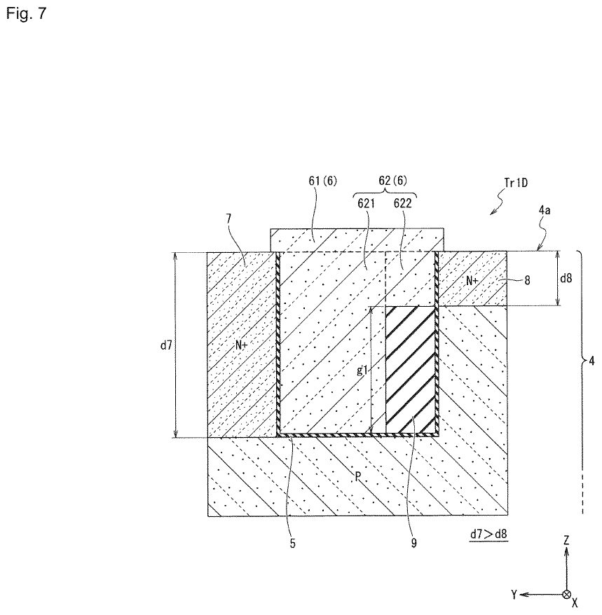

FIG. 7 is a cross-sectional view showing a MOS transistor Tr1D according to the fourth modified example of the first embodiment of the present disclosure. As shown in FIG. 7, in the MOS transistor Tr1D according to the fourth modified example of the first embodiment, the depth d7 from the surface of the source region 7 is deeper than the depth d8 from the surface of the drain region 8 (d7>d8).

Further, in the first buried gate portion 62, the thickness of the first site 621 from the front surface 4a is the same as the depth of the source region 7 from the front surface 4a, and the thickness of the second site 622 from the front surface 4a is the same as the depth of the drain region 8 from the front surface 4a. That is, the first site 621 is formed to have a thickness (depth) that follows the source region 7, and the second site 622 is formed to have a thickness (depth) that follows the drain region 8. Although not shown in FIG. 7, the second buried gate portion 63 also has the same configuration as the first buried gate portion 62.

Even with this configuration, the MOS transistor Tr1D has the thin second sites 622 and 632, which face the drain region 8, so that the gate-drain capacitance Cgd can be reduced similarly to the MOS transistor Tr1.

Further, the deeper the source region 7 is formed from the front surface 4a of the semiconductor substrate 4, the longer the distance between the lower part of the source region 7 and the drain region 8 can be made, and the longer the lower gate length extending from the lower part of the source region 7 to the drain region can be made. Even when reducing the size of the MOS transistor Tr1D in plan view, the lower gate length can be increased by forming the source region 7 deeply, so that the short channel effect of the MOS transistor Tr1D may be suppressed. This structure may be advantageous for miniaturization.

Furthermore, since the drain region 8 is shallower than the source region 7 in terms of the depth from the front surface 4a of the semiconductor substrate 4, it is also possible to make the element separation layer 10 around the drain region 8 shallower.

In addition, also in the fourth modified example shown in FIG. 7, the insulating film 9 is formed in multiple steps as in the second modified example shown in FIG. 5, or the surface or side surface of the insulating film 9 may be inclined as in the third modified example shown in FIG. 6.

### 3. Second Embodiment

### 3-1. Exemplary Configuration

In the first embodiment described above, it has been described that the insulating film 9 is disposed on the drain region 8 side at the bottom of each of the first trench H1 and the second trench H2. However, in the embodiment of the present disclosure, the arrangement of the insulating film 9 is not limited to the drain region 8 side. In the embodiment of the present disclosure, the insulating film 9 may be on the source region 7 side at the bottom of each of the first trench H1 and the second trench H2.

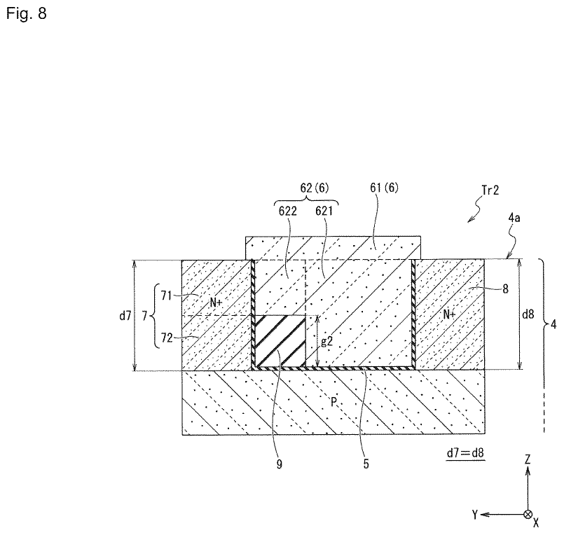

FIG. 8 is a cross-sectional view showing an exemplary configuration of the MOS transistor Tr2 according to the second embodiment of the present disclosure. As shown in FIG. 8, in the MOS transistor Tr2, an insulating film 9 is provided at a position adjacent to the source region 7 at the bottom of the first trench H1. The first site 621 of the first buried gate portion 62 is located on the drain region 8 side, and the second site 622 is located on the source region 7 side. The second site 622 is located between the first site 621 and the source region 7.

At the bottom of the first trench H1, a step g2 due to the insulating film 9 is present between the first site 621 and the second site 622. The second site 622 on the source region 7 side is thinner than the first site 621 by the amount of the insulating film 9 (that is, the amount of the step g2). Although not shown in FIG. 8, the second buried gate portion 63 also has the same configuration as the first buried gate portion 62.

In this way, it is possible to reduce the gate-source capacitance Cgs generated between the gate electrode 6 and the source region 7 compared to the case where the insulating film 9 is not present on the source region 7 side (that is, the case where the step g2 is not present).

Furthermore, the effective depth of the source region 7 is shallower than when the insulating film 9 is not present on the source region 7 side (that is, when the step g2 is not present). The source region 7 has an effective region 71 that actually functions as a source, and a low effective region 72 whose function as a source is lower than that of the effective region 71. The low effective region 72 is located below the effective region 71.

### 3-2. Effects of Second Embodiment

The MOS transistor Tr2 according to the second embodiment of the present disclosure has the thin second sites 622 and 632, which face the source region 7, so that the gate-source capacitance Cgs can be reduced.

In addition, in the MOS transistor Tr2, since the thin second sites 622 and 632 are located on the source region 7 side, a potential gradient that promotes the flow of electrons from the source region 7 to the drain region 8 side is formed in the semiconductor region 41 (see FIG. 2C) where the channel is formed. Therefore, the MOS transistor Tr2 can be suitably used as the reset transistor 36 of the readout circuit 30.

When using the MOS transistor Tr2 as the reset transistor 36, the source region 7 of the MOS transistor Tr2 is connected to the floating diffusion FD, and the drain region 8 of the MOS transistor Tr2 is connected to the power supply potential Vdd. As described above, in the MOS transistor Tr2, a potential gradient is formed that promotes the flow of electrons from the source region 7 to the drain region 8, so that reset feedthrough can be reduced.

Note that reset feedthrough is a phenomenon in which, when the reset transistor is switched from on to off, electrons that had been moving from the source region to the drain region of the reset transistor return to the floating diffusion side, and the potential of the floating diffusion decreases. By reducing the reset feedthrough, it becomes possible to more fully reset the potential of the floating diffusion FD.

### 4. Third Embodiment

### 4-1. Exemplary Configuration

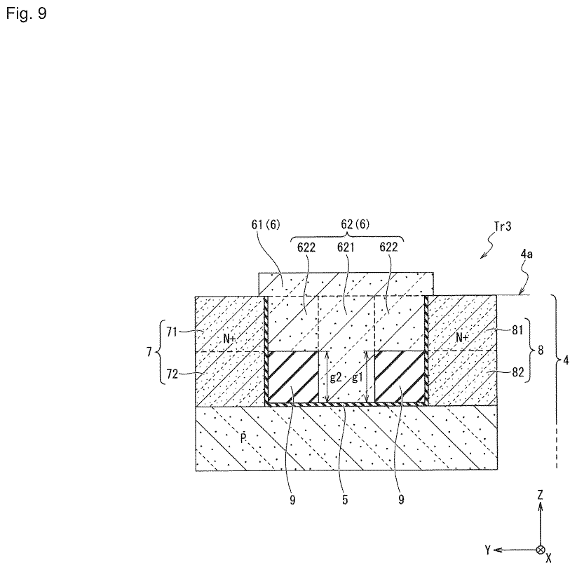

The present disclosure may combine the configurations of the first and second embodiments above. FIG. 9 is a cross-sectional view showing an exemplary configuration of a MOS transistor Tr3 according to the third embodiment of the present disclosure. As shown in FIG. 9, in the MOS transistor Tr3, an insulating film 9 is provided at the bottom of the first trench H1 at a position adjacent to the drain region 8 and at a position adjacent to the source region 7. The first site 621 of the first buried gate portion 62 is located at the center of the MOS transistor Tr3 in the gate length direction. The second site 622 is located on the source region 7 side and the drain region 8 side, respectively. The second site 622 is located between the first site 621 and the source region 7 and between the first site 621 and the drain region 8, respectively.

At the bottom of the first trench H1, there are steps g1 and g2 due to the insulating film 9 between the first site 621 and the second site 622. The second site 622 on the drain region 8 side is thinner than the first site 621 by the amount of the insulating film 9 (that is, the amount of the step g1). Further, the second site 622 on the source region 7 side is thinner than the first site 621 by the amount of the insulating film 9 (that is, the amount of the step g2). Although not shown in FIG. 9, the second buried gate portion 63 also has the same configuration as the first buried gate portion 62.

### 4-2. Effects of Third Embodiment

The MOS transistor Tr3 according to the third embodiment of the present disclosure includes the first sites 621 and 631 and the second sites 622 and 632 that are thinner than the first sites 621 and 631, and the second sites 622 and 632 face the drain region 8 and the source region 7, respectively. In this way, the MOS transistor Tr3 can reduce both the gate-drain capacitance Cgd and the gate-source capacitance Cgs.

### 5. Fourth Embodiment

### 5-1. Exemplary Configuration

Each configuration of the MOS transistors Tr1 to Tr1D according to the first embodiment of the present disclosure may be applied to, for example, the transfer transistor 32 of the readout circuit 30 shown in FIG. 1.

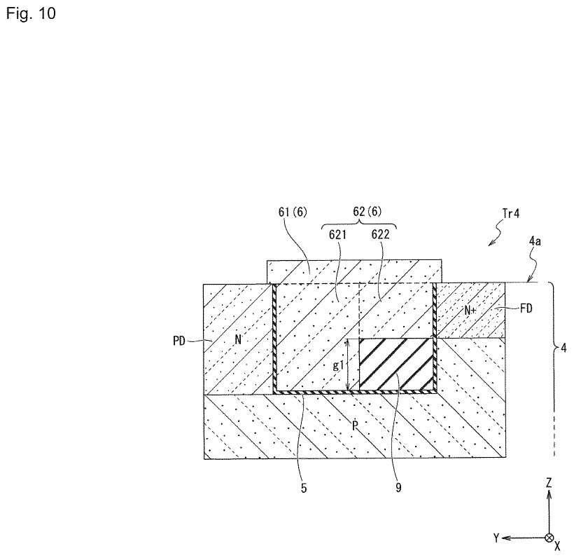

FIG. 10 is a cross-sectional view showing an exemplary configuration of a MOS transistor Tr4 according to the fourth embodiment of the present disclosure. The MOS transistor Tr4 shown in FIG. 10 is used to transfer charges generated by photoelectric conversion in the photodiode PD to the floating diffusion FD, and is used as the transfer transistor 32 of the readout circuit 30. Hereinafter, the MOS transistor Tr4 will also be referred to as a transfer transistor. In the transfer transistor Tr4, the source region is a photodiode PD made of an N-type layer or the like, and the drain region is a floating diffusion FD made of an N+ type layer or the like.

As shown in FIG. 10, in the transfer transistor Tr4, an insulating film 9 is provided at a position adjacent to the drain region 8 at the bottom of the first trench H1. The first site 621 of the first buried gate portion 62 is located on the photodiode PD side, and the second site 622 is located on the floating diffusion FD side. The second site 622 is located between the first site 621 and the floating diffusion FD.

At the bottom of the first trench H1, a step g1 due to the insulating film 9 is present between the first site 621 and the second site 622. The second site 622 is thinner than the first site 621 by the amount of the insulating film 9 (that is, the amount of the step g1). Although not shown in FIG. 10, the second buried gate portion 63 also has the same configuration as the first buried gate portion 62.

### 5-2. Effects of Fourth Embodiment

The transfer transistor Tr4 according to the fourth embodiment of the present disclosure includes the first sites 621 and 631 and the second sites 622 and 632 that are thinner than the first sites 621 and 631, and the second sites 622 and 632 face the floating diffusion FD. In this way, the MOS transistor Tr4 can reduce the capacitance (corresponding to a part of Cgd) generated between the first buried gate portion 62 and the second buried gate portion 63 and the floating diffusion FD.

### 5-3. First Modified Example

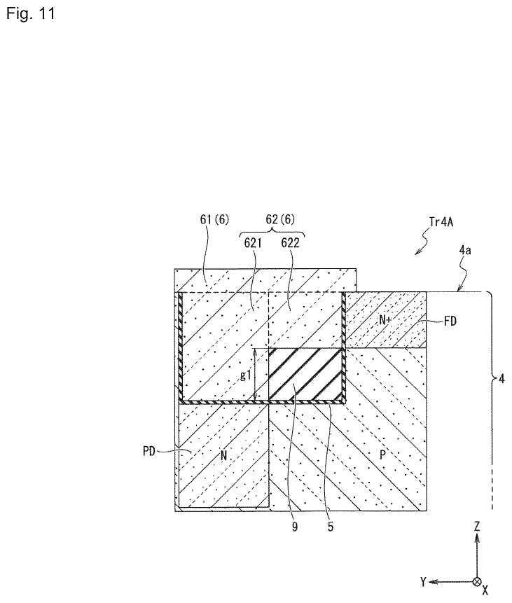

FIG. 11 is a plan view showing a transfer transistor Tr4A according to the first modified example of the fourth embodiment of the present disclosure. As shown in FIG. 11, in the transfer transistor Tr4A, the photodiode PD is arranged under the first site 621 of the first buried gate portion 62 and under the first site 631 of the second buried gate portion 63 (although not shown in FIG. 11). Even with such a configuration, the transfer transistor Tr4A can reduce the capacitance (corresponding to a part of Cgd) generated between the first buried gate portion 62 and the second buried gate portion 63 and the floating diffusion FD similarly to the transfer transistor Tr4.

### 5-4. Second Modified Example

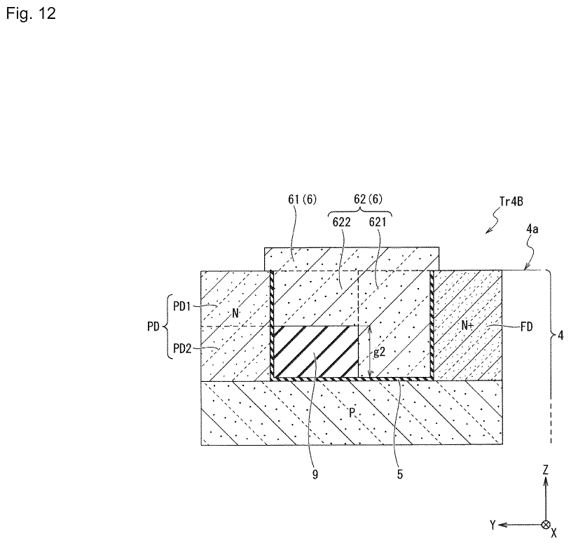

FIG. 12 is a plan view showing a transfer transistor Tr4B according to the second modified example of the fourth embodiment of the present disclosure. As shown in FIG. 12, in the transfer transistor Tr4B, an insulating film 9 is provided at the bottom of the first trench H1 and adjacent to the photodiode PD. The first site 621 of the first buried gate portion 62 is located on the floating diffusion FD side, and the second site 622 is located on the photodiode PD side. The second site 622 is located between the first site 621 and the photodiode PD.

At the bottom of the first trench H1, a step g2 due to the insulating film 9 is present between the first site 621 and the second site 622. The second site 622 on the photodiode PD side is thinner than the first site 621 by the amount of the insulating film 9 (that is, the amount of the step g2). Although not shown in FIG. 12, the second buried gate portion 63 also has the same configuration as the first buried gate portion 62.

In this way, it is possible to reduce the capacitance (corresponding to Cgs) generated between the gate electrode 6 and the photodiode PD compared to the case where the insulating film 9 is not present on the photodiode PD side (that is, the case where the step g2 is not present).

Furthermore, the effective depth of the photodiode PD is shallower than when the insulating film 9 is not present on the photodiode PD side (that is, when the step g2 is not present). The photodiode PD has a first site PD1 adjacent to the second site 622 and a second site PD2 adjacent to the insulating film 9. A second site PD2 is located below the first site PD1.

In the transfer transistor Tr4B, since the thin second sites 622 and 632 are located on the photodiode PD side, a potential gradient that promotes the flow of electrons from the photodiode PD to the floating diffusion FD side is formed in the semiconductor region 41 where the channel is formed (see FIG. 2C). Therefore, it is possible to improve the electron transfer efficiency by the transfer transistor Tr4B.

### 6. Other Embodiments

While the present disclosure has been described on the basis of the embodiment and modified examples as described above, the descriptions and figures that constitute parts of the present disclosure should not be understood as limiting the present disclosure. Various alternative embodiments, examples, and operable techniques will be apparent to those skilled in the art from the present disclosure.

For example, by using one of the MOS transistors Tr1 to Tr1D according to the first embodiment as the amplification transistor 34 of the readout circuit 30, using the MOS transistor Tr2 according to the second embodiment as the reset transistor 36 of the readout circuit 30, and using one of the transfer transistors Tr4 to Tr4B according to the fourth embodiment as the transfer transistor 32 of the readout circuit 30, it is possible to improve the performance of the imaging device 1 including the readout circuit 30.

Further, in the above-described embodiments and modified examples thereof, a case has been described in which the first conductivity type is N-type and the second conductivity type is P-type, but the present disclosure is not limited thereto. The first conductivity type may be P-type, and the second conductivity type may be N-type.

In this way, it is of course that the present technology includes various embodiments and the like that are not described herein. At least one of various omissions, substitutions and modified examples of components may be performed without departing from the gist of the embodiments and the modified examples described above. Furthermore, the effects described in the present description are merely exemplary and not intended to be limiting, and other effects may be provided as well.

The present disclosure can also be configured as follows.
(1)

An imaging device including:
a photoelectric conversion element; and
a semiconductor device that reads charge generated by the photoelectric conversion element,
the semiconductor device including:
a semiconductor substrate; and
a field-effect transistor provided on a first surface side of the semiconductor substrate,
the field-effect transistor including:
a gate electrode including a buried gate portion buried from the first surface of the semiconductor substrate toward an inside of the semiconductor substrate;
a gate insulating film disposed between the semiconductor substrate and the gate electrode;
a source region provided on the semiconductor substrate and connected to one side of the gate electrode in a gate length direction of the gate electrode; and
a drain region connected to the other side of the gate electrode in the gate length direction, and
the buried gate portion including:
a first site; and
a second site located between at least one of the source region and the drain region and the first site, and having a thickness from the first surface smaller than that of the first site.
(2)

The imaging device according to (1), wherein
the thickness of the buried gate portion decreases stepwise or gradually from the first site to the second site.
(3)

The imaging device according to (1) or (2), further including:
a trench which is provided on the first surface side of the semiconductor substrate, and in which the buried gate portion is arranged; and
an insulating film which is disposed at a bottom of the trench, wherein a depth of the trench from the first surface to the insulating film is shallower in a region where the second site is arranged than in a region where the first site is arranged.
(4)

The imaging device according to (3), wherein
a step due to the insulating film is present at the bottom of the trench, and
the thickness of the second site is smaller than the thickness of the first site by an amount of the step.
(5)

The imaging device according to (3) or (4), wherein
the depth of the trench becomes shallower stepwise or gradually from a region where the first site is arranged to a region where the second site is arranged.
(6)

The imaging device according to any one of (3) to (5), wherein
the trench includes:
a first trench; and
a second trench arranged in parallel with the first trench in a direction intersecting the gate length direction of the field-effect transistor, and
the buried gate portion includes:
a first buried gate portion disposed within the first trench; and
a second buried gate portion disposed within the second trench.
(7)

The imaging device according to any one of (1) to (6), wherein
the semiconductor device includes:
an amplification transistor that amplifies a voltage signal corresponding to a level of charge output from the photoelectric conversion element,
the second site is located between the first site and the drain region, and
the field-effect transistor is used as the amplification transistor.
(8)

The imaging device according to any one of (1) to (6), wherein
the semiconductor device includes:
a transfer transistor electrically connected to the photoelectric conversion element,
the second site is located between the first site and the drain region, and
the field-effect transistor is used as the transfer transistor.
(9)

The imaging device according to any one of (1) to (6), wherein
the semiconductor device includes:
a floating diffusion that temporarily holds the charge output from the photoelectric conversion element;
a reset transistor that resets a potential of the floating diffusion to a preset potential,
the second site is located between the first site and the source region, and
the field-effect transistor is used as the reset transistor.
(10)

A semiconductor device including:
a semiconductor substrate; and
a field-effect transistor provided on a first surface side of the semiconductor substrate,
the field-effect transistor including:
a gate electrode including a buried gate portion buried from the first surface of the semiconductor substrate toward an inside of the semiconductor substrate;
a gate insulating film disposed between the semiconductor substrate and the gate electrode;
a source region provided on the semiconductor substrate and connected to one side of the gate electrode in a gate length direction of the gate electrode; and
a drain region connected to the other side of the gate electrode in the gate length direction, and
the buried gate portion including:
a first site; and
a second site located between at least one of the source region and the drain region and the first site, and having a thickness from the first surface smaller than that of the first site.

### REFERENCE SIGNS LIST

1 Imaging device
4 Semiconductor substrate
4a Surface
5 Gate insulating film
6 Gate electrode
7 Source region
8 Drain region
9 Insulating film
10 Element separation layer
12 Pixel region
13 Vertical drive circuit
14 Column signal processing circuit
15 Horizontal drive circuit
16 Output circuit
17 Control circuit
21 Sensor pixel
22 Horizontal signal line
23 Vertical signal line
24 Data output signal line
30 Readout circuit
31 Photodiode
32 Transfer transistor
33 Floating diffusion
34 Amplification transistor
35 Selection transistor
36 Reset transistor
41 Semiconductor region
41a Upper surface
41b First side surface
41c Second side surface
61 Top gate portion
62 First buried gate portion
63 Second buried gate portion
64 Third buried gate portion
71 Effective region
72 Low effective region
81 Effective region
82 Low effective region
91 Thin film portion
92 Thick film portion
621, 631, 641 first site
622, 632, 642 second site
Cgd Gate-drain capacitance
Cgs Gate-source capacitance
FD Floating diffusion
g1, g2 Step
H1 First trench
H2 Second trench
M1, M2 Mask
PD Photodiode
PD1 first site
PD2 second site
RST Reset signal
SEL Selection signal
Tr MOS transistor
Tr1, Tr1A, Tr1B, Tr1C, Tr1D, Tr2, Tr3 MOS transistor
Tr4, Tr4A, Tr4B MOS transistor (transfer transistor)
TRG Transfer signal
Vdd Power supply potential

1. An imaging device comprising:
a photoelectric conversion element; and
a semiconductor device that reads charge generated by the photoelectric conversion element,
the semiconductor device including:
a semiconductor substrate; and
a field-effect transistor provided on a first surface side of the semiconductor substrate,
the field-effect transistor including:
a gate electrode including a buried gate portion buried from the first surface of the semiconductor substrate toward an inside of the semiconductor substrate;
a gate insulating film disposed between the semiconductor substrate and the gate electrode;
a source region provided on the semiconductor substrate and connected to one side of the gate electrode in a gate length direction of the gate electrode; and
a drain region connected to the other side of the gate electrode in the gate length direction, and
the buried gate portion including:
a first site; and
a second site located between at least one of the source region and the drain region and the first site, and having a thickness from the first surface smaller than that of the first site.

2. The imaging device according to claim 1, wherein
the thickness of the buried gate portion decreases stepwise or gradually from the first site to the second site.

3. The imaging device according to claim 1, further comprising:
a trench which is provided on the first surface side of the semiconductor substrate, and in which the buried gate portion is arranged; and
an insulating film which is disposed at a bottom of the trench, wherein
a depth of the trench from the first surface to the insulating film is shallower in a region where the second site is arranged than in a region where the first site is arranged.

4. The imaging device according to claim 3, wherein
a step due to the insulating film is present at the bottom of the trench, and
the thickness of the second site is smaller than the thickness of the first site by an amount of the step.

5. The imaging device according to claim 3, wherein
the depth of the trench becomes shallower stepwise or gradually from a region where the first site is arranged to a region where the second site is arranged.

6. The imaging device according to claim 3, wherein
the trench includes:
a first trench; and
a second trench arranged in parallel with the first trench in a direction intersecting the gate length direction of the field effect transistor, and
the buried gate portion includes:
a first buried gate portion disposed within the first trench; and
a second buried gate portion disposed within the second trench.

7. The imaging device according to claim 1, wherein
the semiconductor device includes:
an amplification transistor that amplifies a voltage signal corresponding to a level of charge output from the photoelectric conversion element,
the second site is located between the first site and the drain region, and
the field-effect transistor is used as the amplification transistor.

8. The imaging device according to claim 1, wherein
the semiconductor device includes:
a transfer transistor electrically connected to the photoelectric conversion element,
the second site is located between the first site and the drain region, and
the field-effect transistor is used as the transfer transistor.

9. The imaging device according to claim 1, wherein
the semiconductor device includes:
a floating diffusion that temporarily holds the charge output from the photoelectric conversion element;
a reset transistor that resets a potential of the floating diffusion to a preset potential,
the second site is located between the first site and the source region, and the field-effect transistor is used as the reset transistor.

10. A semiconductor device comprising:
a semiconductor substrate; and
a field-effect transistor provided on a first surface side of the semiconductor substrate,
the field-effect transistor including:
a gate electrode including a buried gate portion buried from the first surface of the semiconductor substrate toward an inside of the semiconductor substrate;
a gate insulating film disposed between the semiconductor substrate and the gate electrode;
a source region provided on the semiconductor substrate and connected to one side of the gate electrode in a gate length direction of the gate electrode; and
a drain region connected to the other side of the gate electrode in the gate length direction, and
the buried gate portion including:
a first site; and
a second site located between at least one of the source region and the drain region and the first site, and having a thickness from the first surface smaller than that of the first site.
